(19) United States
(12) Patent Application Publication
(10) Pub. No.: US 2008/0157657 A1
(43) Pub. Date: Jul. 3, 2008

(54) ORGANIC ELECTROLUMINESCENT DEVICE AND DISPLAY

(75) Inventors: Shigeyuki Matsunami, Kanagawa (JP); Masayuki Kurotaki, Kanagawa (JP); Toshihiro Fukuda, Kanagawa (JP); Yasunori Kijima, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/959,694

(22) Filed: Dec. 19, 2007

(30) Foreign Application Priority Data
Dec. 22, 2006 (JP) 2006-346068

(51) Int. Cl. H01L 51/54

(52) U.S. Cl. 313/504

(57) ABSTRACT

According to an embodiment of the present invention, there is provided an organic electroluminescent device for emitting red light having an organic layer that includes a light-emitting layer and is provided between an anode and a cathode. The light-emitting layer contains a red light-emitting guest material and a host material that is composed of a polycyclic aromatic hydrocarbon compound having a skeleton with four- to seven-membered rings. Furthermore, a light-enhancing layer that contains a light-emitting guest material for generating light having a wavelength shorter than that of light emitted by the light-emitting layer is provided adjacent to the light-emitting layer.

### CROSS REFERENCES TO RELATED APPLICATIONS

The present invention contains subject matter related to Japanese Patent Application JP 2006-346068 filed in the Japanese Patent Office on Dec. 22, 2006, the entire contents of which being incorporated herein by reference.

### BACKGROUND OF THE INVENTION

1. Field of the Invention

The present invention relates to an organic electroluminescent device and a display and particularly to an organic electroluminescent device for emitting red light and a display employing the same.

2. Description of Related Art

In recent years, displays employing organic electroluminescent devices (so-called organic EL elements) are attracting attention as light-weight and high-efficiency flat panel displays.

The organic electroluminescent device included in such a display is provided over a transparent substrate composed of e.g. glass, and is formed by stacking an anode composed of indium tin oxide (ITO: transparent electrode), an organic layer, and a cathode in that order from the substrate side. The organic layer has a structure obtained by sequentially stacking a hole injection layer, a hole transport layer, and an electron-transport light-emitting layer in that order from the anode side. In the thus formed organic electroluminescent device, electrons injected from the cathode and holes injected from the anode are recombined with each other in the light-emitting layer, so that light arising from the recombination is extracted from the substrate side via the anode.

As the organic electroluminescent device, besides one having such a structure, a so-called top-emission element is also known. In the top-emission element, a cathode, an organic layer, and an anode are sequentially stacked in that order from the substrate side. Furthermore, the electrode disposed on the upper side of the element (upper electrode as the cathode or anode) is formed by using a transparent material to thereby allow extraction of light from the upper electrode side opposite to the substrate. In particular, for an active-matrix display formed by providing thin film transistors (TFTs) over a substrate, it is more advantageous to have a so-called top-emission structure, in which top-emission organic electroluminescent devices are provided over the substrate on which the TFTs are formed, in terms of enhancement in the aperture ratio of the light-emitting part.

In view of practical use of an organic EL display, there is a need not only to enlarge the apertures of organic electroluminescent devices to thereby enhance the light extraction degree but also to enhance the light emission efficiency of the organic electroluminescent devices. Therefore, studies have been made on various materials and layer configurations for achieving enhanced light emission efficiency.

For example, for a red light-emitting element, there has been proposed a configuration in which a naphthacene derivative (including a rubrene derivative) is used as a dopant material as a novel red light-emitting material to replace pyran derivatives typified by DCJTB (refer to e.g. Japanese Patent Laid-open No. 2000-26334 and Japanese Patent Laid-open No. 2003-55652 (in particular, Paragraphs 0353 to 0357, Table 11)). Furthermore, Japanese Patent Laid-open No. 2002-8867 proposes a configuration in which a rubrene derivative is used as a host material and a diindeno[1,2,3-cd]perylene derivative is used as a light-emitting guest material.

In addition, in the above-mentioned Japanese Patent Laid-open No. 2003-55652, there has also been proposed a configuration in which a second light-emitting layer including a perylene derivative is stacked on a first light-emitting layer including a rubrene derivative as a dopant material and an anthracene derivative for achievement of while light emission.

Moreover, there has also been proposed a configuration in which an electron transport layer and a hole transport layer adjacent to a blue light-emitting layer are doped with a rubrene derivative for achievement of white light emission (refer to Japanese Patent Laid-open No. 2004-134396).

### SUMMARY OF THE INVENTION

For full-color displaying by the above-described display, organic electroluminescent devices for light emission of the respective colors of the three primary colors (red, green, and blue) are arranged. Alternatively, organic electroluminescent devices for white light emission and color filters or color conversion layers for the respective colors are combined. In terms of the extraction efficiency of emitted light, the configuration employing the organic electroluminescent devices that emit light of the respective colors is more advantageous.

However, in the light emission of the above-described red light-emitting element employing a naphthacene derivative (rubrene derivative), the current efficiency is as low as about 6.7 cd/A, and the emission color is orange rather than red.

There is a need for the present invention to provide an organic electroluminescent device for emitting red light having sufficiently-favorable light emission efficiency and color purity and a display employing the same.

According to one embodiment of the present invention, there is provided an organic electroluminescent device for emitting red light having an organic layer including a light-emitting layer provided between an anode and a cathode. The light-emitting layer contains a red light-emitting guest material and a host material that is composed of a polycyclic aromatic hydrocarbon compound having a skeleton with four- to seven-membered rings. As the red light-emitting guest material, e.g. a perylene derivative is used. Furthermore, a light-enhancing layer that contains a light-emitting guest material for generating light having a wavelength shorter than that of light emitted by the light-emitting layer is provided adjacent to the light-emitting layer.

As described in detail later in the explanation of working examples of the present invention, it is found that the organic electroluminescent device having such a configuration has higher current efficiency compared with a configuration including no light-enhancing layer. Furthermore, it is also found that only red light generated by the light-emitting layer is extracted from the element without being affected by the light-enhancing layer containing a light-emitting material.

According to another embodiment of the present invention, there is provided a display formed by arranging plural organic electroluminescent devices having the above-described configuration over a substrate.

In this display, organic electroluminescent devices having high luminance and color purity are used as red light-emitting elements as described above. Thus, combining these elements with green and blue light-emitting elements allows the display to carry out full-color displaying with high color reproducibility.

As described above, the organic electroluminescent device according to one embodiment of the present invention is allowed to enhance the light emission efficiency of red light while keeping the color purity thereof.

Furthermore, the display according to another embodiment of the present invention is allowed to carry out full-color displaying with high color reproducibility when the pixels therein are formed by paring the organic electroluminescent device serving as a red light-emitting element having high color purity and light emission efficiency as described above with green and blue light-emitting elements.

### BRIEF DESCRIPTION OF THE DRAWINGS

FIG. 1 is a sectional view of an organic electroluminescent device according to an embodiment of the present invention;

FIGS. 2A and 2B are diagrams showing one example of the circuit arrangement in a display according to the embodiment;

FIG. 3 is a diagram showing a first example of the sectional configuration of major part of the display according to the embodiment;

FIG. 4 is a diagram showing a second example of the sectional configuration of major part of the display according to the embodiment;

FIG. 5 is a diagram showing a third example of the sectional configuration of major part of the display according to the embodiment;

FIG. 6 is a diagram showing a fourth example of the sectional configuration of major part of the display according to the embodiment;

FIG. 7 is a diagram showing a fifth example of the sectional configuration of major part of the display according to the embodiment;

FIG. 8 is a diagram showing a sixth example of the sectional configuration of major part of the display according to the embodiment;

FIG. 9 is a diagram showing a seventh example of the sectional configuration of major part of the display according to the embodiment;

FIG. 10 is a configuration diagram showing a module-shape display having a sealed structure to which the embodiment is applied;

FIG. 11 is a perspective view showing a television to which the embodiment is applied;

FIGS. 12A and 12B are diagrams showing a digital camera to which the embodiment is applied: FIG. 12A is a front-side perspective view and FIG. 12B is a rear-side perspective view;

FIG. 13 is a perspective view showing a notebook personal computer to which the embodiment is applied;

FIG. 14 is a perspective view showing a video camera to which the embodiment is applied; and

FIGS. 15A to 15G are diagrams showing a cellular phone as portable terminal apparatus to which the embodiment is applied: FIGS. 15A and 15B are a front view and side view, respectively, of the opened state, and FIGS. 15C, 15D, 15E, 15F, and 15G are a front view, left-side view, right-side view, top view, and bottom view, respectively, of the closed state.

### DETAILED DESCRIPTION OF THE PREFERRED EMBODIMENTS

An embodiment of the present invention will be described in detail below based on the drawings, in the order of an organic electroluminescent device and a display employing the same.

### <<Organic Electroluminescent Device>>

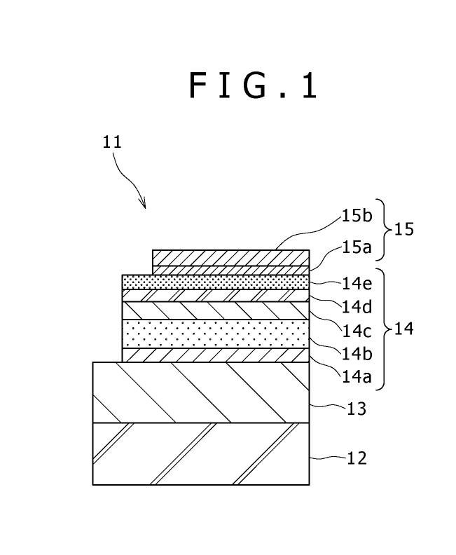

FIG. 1 is a sectional view schematically showing an organic electroluminescent device according to the embodiment. An organic electroluminescent device 11 shown in this drawing is formed by stacking, over a substrate 12, an anode 13, an organic layer 14, and a cathode 15 in that order. The organic layer 14 is obtained e.g. by sequentially stacking a hole injection layer 14a, a hole transport layer 14b, a light-emitting layer 14c, a light-enhancing layer 14d, and an electron transport layer 14e in that order from the anode 13 side.

Features of the present embodiment exist in the configuration of the light-emitting layer 14c and the provision of the light-enhancing layer 14d in contact with the light-emitting layer 14c. The following description is based on an assumption that the organic electroluminescent device 11 having such a multilayer structure is formed as a top-emission element from which light is extracted from the side opposite to the substrate 12. Details of the respective layers of this element will be described below sequentially from the substrate 12 side.

### <Substrate>

The substrate 12 is a support member, and the organic electroluminescent devices 11 are arranged on one major surface side thereof. A publicly-known material may be used for the substrate 12, and e.g. quartz, glass, metal foil, resin film, or resin sheet is used as the substrate 12. Of these materials, quartz and glass are preferable. Examples of the resin material include methacrylic resins typified by polymethylmethacrylate (PMMA), polyesters such as polyethylene terephthalate (PET), polyethylene naphthalate (PEN), and polybutylene naphthalate (PBN), and polycarbonate resins. However, when a resin material is used, it is necessary for the substrate 12 to have a multilayer structure or be subjected to surface treatment for suppressing water permeability and gas permeability.

### <Anode>

For the anode 13, an electrode material of which work function with respect to the vacuum level is large is used for efficient hole injection. Examples of the material include metals such as aluminum (Al), chromium (Cr), molybdenum (Mo), tungsten (W), copper (Cu), silver (Ag), and gold (Au), alloys of these metals, and oxides of these metals and alloys. In addition, the examples of the material further include an alloy of tin oxide (SnO₂) and antimony (Sb), indium tin oxide (ITO), indium zinc oxide (InZnO), an alloy of zinc oxide (ZnO) and aluminum (Al), and oxides of these metals and alloys. Any of these materials is used alone or in a mixed state for the anode 13.

The anode 13 may have a multilayer structure formed of a first layer superior in the light reflectivity and a second layer that is provided over the first layer and has optical transparency and a large work function.

The first layer is formed of an alloy composed mainly of aluminum. The minor component of the first layer may be a substance containing at least one element of which work function is relatively smaller than that of aluminum as the major component. A lanthanoid element is preferable as such a minor component. Although the work function of the lanthanoid elements is not large, the presence of any of these elements enhances the stability of the anode and allows the anode to achieve a favorable hole injection property. Furthermore, as the minor component, besides a lanthanoid element, another element such as silicon (Si) or copper (Cu) may be contained.

It is preferable that the total minor-component content in the aluminum alloy layer of the first layer be about 10 wt % or lower when the minor component is e.g. Nd, Ni, or Ti, which stabilizes aluminum. Such minor-component content maintains the reflectivity of the aluminum alloy layer and stably keeps the aluminum alloy layer in the manufacturing process for the organic electroluminescent device. Furthermore, processing accuracy and chemical stability can also be achieved. In addition, the electric conductivity of the anode 13 and the adhesion with the substrate 12 can also be improved.

Examples of the second layer include a layer containing at least one of an oxide of an aluminum alloy, an oxide of molybdenum, an oxide of zirconium, an oxide of chromium, and an oxide of tantalum. For example, when the second layer is an oxide layer (including a natural oxide film) of an aluminum alloy containing a lanthanoid element as a minor component, the transmittance of the second layer containing an oxide of the lanthanoid element is favorable because the transmittance of the oxide of the lanthanoid element is high. Consequently, high reflectivity can be kept at the surface of the first layer. The second layer may be a transparent conductive layer such as an indium tin oxide (ITO) or indium zinc oxide (IZO) layer. These conductive layers can improve the hole injection property of the anode 13.

Furthermore, on the surface of the anode 13 in contact with the substrate 12, a conductive layer for enhancing the adhesion between the anode 13 and the substrate 12 may be provided. Examples of such a conductive layer include a transparent conductive layer such as an ITO or IZO layer.

When the drive system for the display formed by using the organic electroluminescent devices 11 is the active-matrix system, the anode 13 is patterned for each pixel and so provided as to be connected to a drive thin film transistor provided on the substrate 12. In this case, an insulating film (not shown) is provided on the anodes 13 in such a way that the surfaces of the anodes 13 of the respective pixels are exposed through apertures in this insulating film.

### <Hole Injection Layer/Hole Transport Layer>

The hole injection layer 14a and the hole transport layer 14b each function to enhance the efficiency of hole injection into the light-emitting layer 14c. Examples of the material of the hole injection layer 14a and the hole transport layer 14b include benzine, styrylamine, triphenylamine, porphyrin, triphenylene, azatriphenylene, tetracyanoquinodimethane, triazole, imidazole, oxadiazole, polyarylalkane, phenylenediamine, arylamine, oxazole, fullerene, anthracene, fluorenone, hydrazone, stilbene, and derivatives of these substances. In addition, the examples of the material further include heterocyclic conjugated monomers, oligomers, and polymers, such as polysilane compounds, vinylcarbazole compounds, thiophene compounds, and aniline compounds.

More specific examples of the material of the hole injection layer 14a and the hole transport layer 14b include α-naphthylphenyldiamine, porphyrin, metal tetraphenylporphyrin, metal naphthalocyanine, C60, C70, hexacyanoazatriphenylene, 7,7,8,8-tetracyanoquinodimethane (TCNQ), 7,7,8,8-tetracyano-2,3,5,6-tetrafluoroquinodimethane (F4-TCNQ), 4,4,4-tris(3-methylphenylphenylamino)triphenylamine, N,N,N′,N′-tetrakis(p-tolyl)p-phenylenediamine, N,N,N′,N′-tetraphenyl-4,4′-diaminobiphenyl, N-phenylcarbazole, 4-di-p-tolylaminostilbene, poly(paraphenylenevinylene), poly(thiophene), poly(thiophenevinylene), and poly(2,2′-thienylpyrrol). Although, the materials are not limited to these components.

### <Light-Emitting Layer>

The light-emitting layer 14c is the region in which holes injected from the anode 13 and electrons injected from the cathode 15 are recombined with each other when voltage is applied between the anode 13 and the cathode 15. One feature of the present embodiment exists in the configuration of the light-emitting layer 14c. Specifically, the light-emitting layer 14c is doped with a red light-emitting guest material and includes as its host material a polycyclic aromatic hydrocarbon compound having a skeleton with four- to seven-membered rings. Thus, the light-emitting layer 14c emits red light.

As the red light-emitting guest material, e.g. a compound represented by General formula (1) (diindeno[1,2,3-cd]perylene derivative) is preferably used.

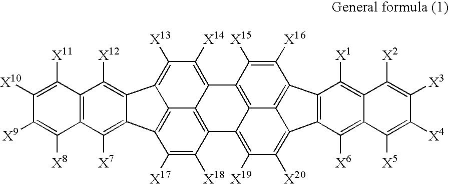

In General formula (1), X¹ to X²⁰ each independently denote hydrogen, a halogen, hydroxyl group, substituted or unsubstituted carbonyl group having 20 or less carbon atoms, substituted or unsubstituted carbonyl ester group having 20 or less carbon atoms, substituted or unsubstituted alkyl group having 20 or less carbon atoms, substituted or unsubstituted alkenyl group having 20 or less carbon atoms, substituted or unsubstituted alkoxyl group having 20 or less carbon atoms, cyano group, nitro group, substituted or unsubstituted silyl group having 30 or less carbon atoms, substituted or unsubstituted aryl group having 30 or less carbon atoms, substituted or unsubstituted heterocyclic group having 30 or less carbon atoms, or substituted or unsubstituted amino group having 30 or less carbon atoms.

Examples of the aryl group denoted by X¹ to X²⁰ in General formula (1) include a phenyl group, 1-naphthyl group, 2-naphthyl group, fluorenyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 1-chrysenyl group, 6-chrysenyl group, 2-fluoranthenyl group, 3-fluoranthenyl group, 2-biphenylyl group, 3-biphenylyl group, 4-biphenylyl group, o-tolyl group, m-tolyl group, p-tolyl group, and p-t-butylphenyl group.

Examples of the heterocyclic group denoted by X¹ to X²⁰ include aromatic heterocyclic groups with five- or six-membered rings that contain O, N, and S as a heteroatom and condensed polycyclic aromatic heterocyclic groups having two to twenty carbon atoms. Examples of these aromatic heterocyclic groups and condensed polycyclic aromatic heterocyclic groups include a thienyl group, furyl group, pyrrolyl group, pyridyl group, quinolyl group, quinoxalyl group, imidazopyridyl group, and benzothiazole group. Representative examples of these groups include a 1-pyrrolyl group, 2-pyrrolyl group, 3-pyrrolyl group, pyrazinyl group, 2-pyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, and 9-acridinyl group.

The amino group denoted by X¹ to X²⁰ may be any of an alkylamino group, arylamino group, aralkylamino group, and so on. It is preferable that these groups have an aliphatic with total carbon number of one to six and/or one- to four-membered aromatic carbon rings. Examples of such a group include a dimethylamino group, diethylamino group, dibutylamino group, diphenylamino group, ditolylamino group, bisbiphenylylamino group, and dinaphthylamino group.

Two or more kinds of the above-described substituents may form a condensed ring and may further have a substituent.

It is preferable that the molecular weight of the diindeno[1,2,3-cd]perylene derivative represented by General formula (1), which is used as the red light-emitting guest material in the light-emitting layer 14c, be 2000 or smaller. Moreover, a molecular weight of 1500 or smaller is more preferable, and 1000 or smaller is particularly preferable. This is because a large molecular weight will cause a fear of unfavorable film-deposition quality in fabrication of the element by evaporation.

Specific examples of the diindeno[1,2,3-cd]perylene derivative, which is favorably used as the red light-emitting guest material in the light-emitting layer 14c, include Compounds (1)-1 to (1)-8 shown below. However, the present invention is not limited thereto at all.

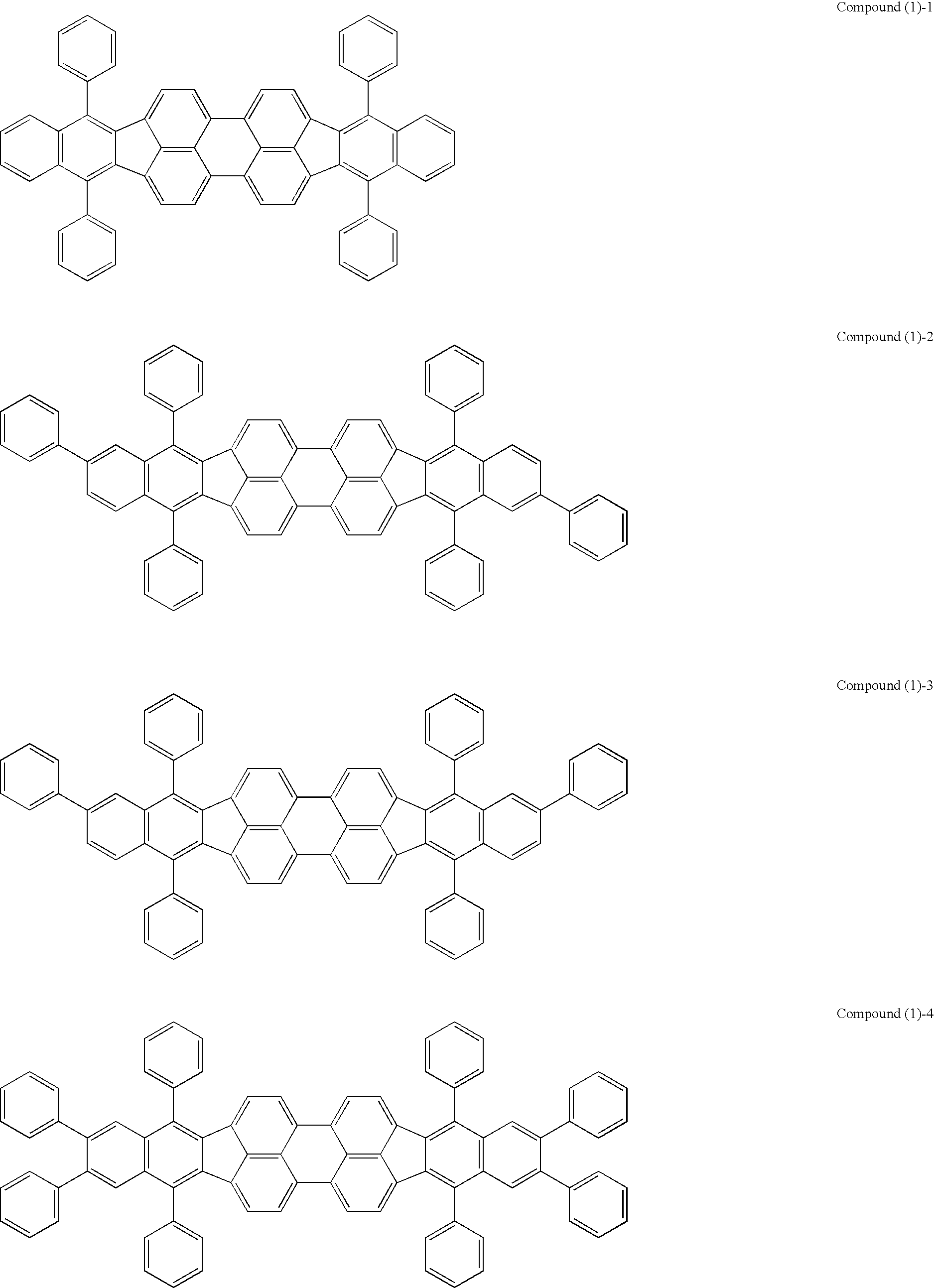

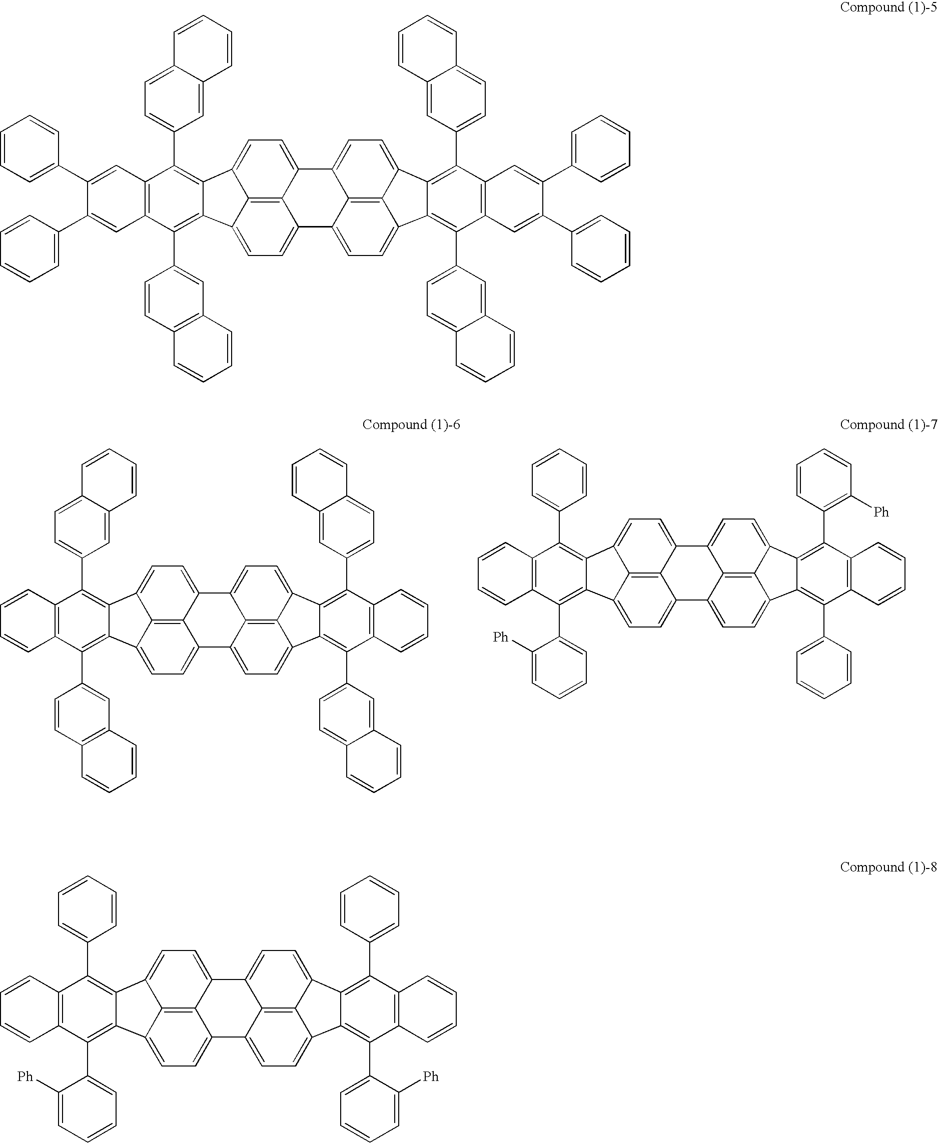

The host material of the light-emitting layer 14c is a polycyclic aromatic hydrocarbon compound having a skeleton with four- to seven-membered rings, and is selected from pyrene, benzopyrene, chrysene, naphthacene, benzonaphthacene, dibenzonaphthacene, perylene, and coronene.

In particular, it is preferable to use a naphthacene derivative represented by General formula (2) as the host material.

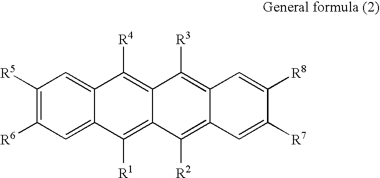

In General formula (2), R¹ to R⁸ each independently denote hydrogen, a halogen, hydroxyl group, substituted or unsubstituted carbonyl group having 20 or less carbon atoms, substituted or unsubstituted carbonyl ester group having 20 or less carbon atoms, substituted or unsubstituted alkyl group having 20 or less carbon atoms, substituted or unsubstituted alkenyl group having 20 or less carbon atoms, substituted or unsubstituted alkoxyl group having 20 or less carbon atoms, cyano group, nitro group, substituted or unsubstituted silyl group having 30 or less carbon atoms, substituted or unsubstituted aryl group having 30 or less carbon atoms, substituted or unsubstituted heterocyclic group having 30 or less carbon atoms, or substituted or unsubstituted amino group having 30 or less carbon atoms.

Examples of the aryl group denoted by R¹ to R⁸ in General formula (2) include a phenyl group, 1-naphthyl group, 2-naphthyl group, fluorenyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 1-chrysenyl group, 6-chrysenyl group, 2-fluoranthenyl group, 3-fluoranthenyl group, 2-biphenylyl group, 3-biphenylyl group, 4-biphenylyl group, o-tolyl group, m-tolyl group, p-tolyl group, and p-t-butylphenyl group.

Examples of the heterocyclic group denoted by R¹ to R⁸ include aromatic heterocyclic groups with five- or six-membered rings that contain O, N, and S as a heteroatom and condensed polycyclic aromatic heterocyclic groups having two to twenty carbon atoms. Examples of these aromatic heterocyclic groups and condensed polycyclic aromatic heterocyclic groups include a thienyl group, furyl group, pyrrolyl group, pyridyl group, quinolyl group, quinoxalyl group, imidazopyridyl group, and benzothiazole group. Representative examples of these groups include a 1-pyrrolyl group, 2-pyrrolyl group, 3-pyrrolyl group, pyrazinyl group, 2-pyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, and 9-acridinyl group.

The amino group denoted by R¹ to R⁸ may be any of an alkylamino group, arylamino group, aralkylamino group, and so on. It is preferable that these groups have an aliphatic with total carbon number of one to six and/or one- to four-membered aromatic carbon rings. Examples of such a group include a dimethylamino group, diethylamino group, dibutylamino group, diphenylamino group, ditolylamino group, bisbiphenylylamino group, and dinaphthylamino group.

Two or more kinds of the above-described substituents may form a condensed ring and may further have a substituent.

In particular, it is preferable that the naphthacene derivative represented by General formula (2) be a rubrene derivative represented by General formula (2a) shown below.

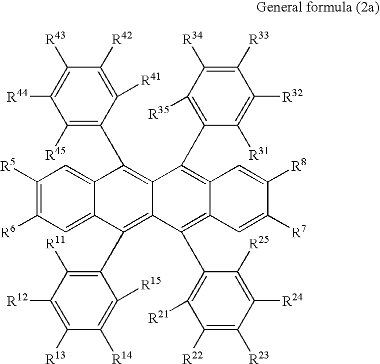

In General formula (2a), R¹¹ to R¹⁵, R²¹ to R²⁵, R³¹ to R³⁵, and R⁴¹ to R⁴⁵ each independently denote a hydrogen atom, aryl group, heterocyclic group, amino group, aryloxy group, alkyl group, or alkenyl group. However, it is preferable that R¹¹ to R¹⁵, R²¹ to R²⁵, R³¹ to R³⁵, and R⁴¹ to R⁴⁵ be identical to each other.

Furthermore, it is preferable that R⁵ to R⁸ in General formula (2a) be each independently an aryl group that may have a hydrogen atom or substituent, or an alkyl group or alkenyl group that may have a substituent.

Preferred forms of the aryl group, the heterocyclic group, and the amino group in General formula (2a) may be the same as those for R¹ to R⁸ in General formula (2). If any of R¹¹ to R¹⁵, R²¹ to R²⁵, R³¹ to R³⁵, and R⁴¹ to R⁴⁵ is an amino group, this amino group is an alkylamino group, arylamino group, or aralkylamino group. It is preferable that these groups have an aliphatic with total carbon number of one to six and/or one- to four-membered aromatic carbon rings. Examples of such a group include a dimethylamino group, diethylamino group, dibutylamino group, diphenylamino group, ditolylamino group, and bisbiphenylylamino group.

More specific other examples of the naphthacene derivative favorably used as the host material of the light-emitting layer 14c include rubrene shown as Compound (2)-1, which is one of the rubrene derivatives of General formula (2a). In addition, Compounds (2)-2 to (2)-4 are also available.

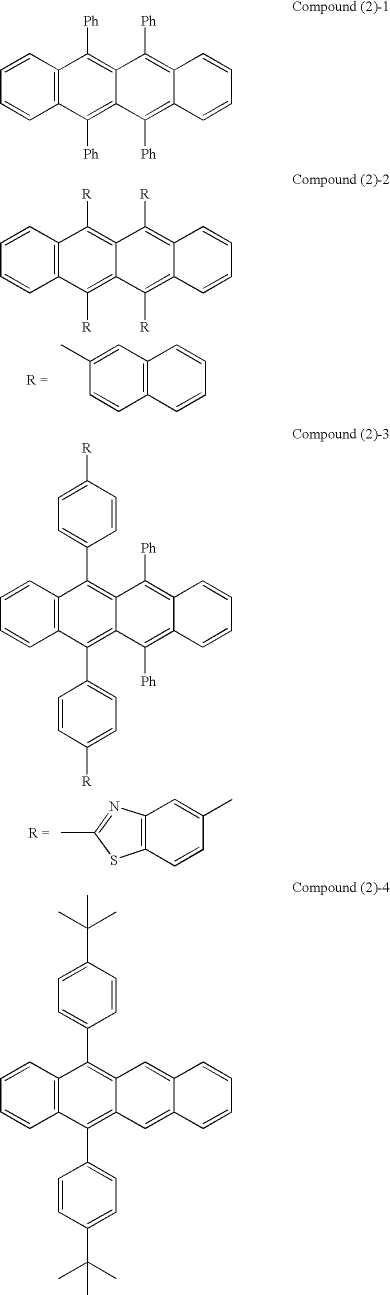

### <Light-Enhancing Layer>

The light-enhancing layer 14d functions to transmit energy to the light-emitting layer 14c to thereby enhance the light emission efficiency of the light-emitting layer 14c. Another one feature of the present embodiment is that such a light-enhancing layer 14d is provided in contact with the light-emitting layer 14c. Such a light-enhancing layer 14d is obtained by doping a host material with a light-emitting guest material that emits light with a wavelength shorter than that of light emitted by the light-emitting layer 14c.

As the light-emitting guest material, a material offering high light emission efficiency is used. Specifically, an organic light-emitting material such as a low-molecular fluorescent dye, fluorescent polymer, or metal complex is used. In the present embodiment, of these materials, a blue light-emitting guest material or green light-emitting guest material is used.

The blue light-emitting guest material refers to a compound that emits light of which peak falls within the wavelength range of about 400 nm to 490 nm. As such a compound, an organic substance such as a naphthalene derivative, anthracene derivative, naphthacene derivative, styrylamine derivative, or bis(azinyl)methene boron complex is used. In particular, it is preferable that the compound be selected from an aminonaphthalene derivative, aminoanthracene derivative, aminochrysene derivative, aminopyrene derivative, styrylamine derivative, and bis(azinyl)methene boron complex.

On the other hand, the green light-emitting guest material refers to a compound that emits light of which peak falls within the wavelength range of about 490 nm to 580 nm. As such a compound, an organic substance such as a naphthalene derivative, anthracene derivative, pyrene derivative, naphthacene derivative, fluoranthene derivative, perylene derivative, coumarin derivative, quinacridone derivative, indeno[1,2,3-cd]perylene derivative, bis(azinyl)methene boron complex, or pyran dye is used. In particular, it is preferable that the compound be selected from an aminoanthracene derivative, fluoranthene derivative, coumarin derivative, quinacridone derivative, indeno[1,2,3-cd]perylene derivative, and bis(azinyl)methene boron complex.

The host material of the light-enhancing layer 14d is an organic material composed of a derivative of an aromatic hydrocarbon of which carbon number is from six to sixty inclusive or an organic material arising from coupling of the derivatives. Specific examples of the organic material include a naphthalene derivative, indene derivative, phenanthrene derivative, pyrene derivative, naphthacene derivative, triphenylene derivative, anthracene derivative, perylene derivative, picene derivative, fluoranthene derivative, acephenanthrylene derivative, pentaphene derivative, pentacene derivative, coronene derivative, butadiene derivative, stilbene derivative, tris(8-quinolinolato) aluminum complex, and bis(benzoquinolinolato) beryllium complex.

As the host material, a material that offers the highest light emission efficiency with respect to the employed light-emitting guest material is selected and used.

It is important that the light-enhancing layer 14d having such a configuration be provided in contact with the light-emitting layer 14c. Therefore, the light-enhancing layer 14d is not limited to the layer provided between the light-emitting layer 14c and the cathode 15 as described above, but may be provided between the light-emitting layer 14c and the anode 13, in contact with the light-emitting layer 14c.

### <Electron Transport Layer>

The electron transport layer 14e functions to transport electrons injected from the cathode 15 into the light-emitting layer 14c. Examples of the material of the electron transport layer 14e include quinoline, perylene, phenanthroline, bisstyryl, pyrazine, triazole, oxazole, fullerene, oxadiazole, fluorenone, and derivatives and metal complexes of these substances. Specific examples of the material include tris(8-hydroxyquinoline) aluminum (Alq3), anthracene, naphthalene, phenanthrene, pyrene, perylene, butadiene, coumarin, C60, acridine, stilbene, 1,10-phenanthroline, and derivatives and metal complexes of these substances.

The organic layer 14 is not limited to the layer having the above-described layer structure but may have another multilayer structure according to need as long as at least the light-emitting layer 14c and the light-enhancing layer 14d in contact with the light-emitting layer 14c are provided in the organic layer 14.

The light-emitting layer 14c may be provided in the organic electroluminescent device 11 as a hole-transport light-emitting layer, electron-transport light-emitting layer, or light-emitting layer that can transport both holes and electrons. Furthermore, each of the layers included in the organic layer 14, such as the hole injection layer 14a, the hole transport layer 14b, the light-emitting layer 14c, the light-enhancing layer 14d, and the electron transport layer 14e, may have a multilayer structure formed of plural layers.

### <Cathode>

The cathode 15 provided on the organic layer 14 with the above-described configuration has e.g. a two-layer structure formed by stacking a first layer 15a and a second layer 15b in that order from the organic layer side.

The first layer 15a is formed by using a material that has a small work function and favorable optical transparency. As such a material, e.g. lithium oxide (Li₂O) as an oxide of lithium (Li), cesium carbonate (Cs₂CO₃) as a composite oxide of cesium (Cs), or a mixture of these oxide and composite oxide can be used. However, the material of the first layer 15a is not limited to these substances. Other examples of the material include alkaline earth metals such as calcium (Ca) and barium (Ba), alkali metals such as lithium and cesium, small-work-function metals such as indium (In) and magnesium (Mg), and oxides, composite oxides, and fluorides of these metals. Any of these metals, oxides, composite oxides, and fluorides may be used alone. Alternatively, a mixture or alloy of these metals, oxides, composite oxides, and fluorides may be used with enhanced stability.

The second layer 15b is formed of an optically-transparent thin film composed of e.g. MgAg. This second layer 15b may be a mixed layer that further contains an organic light-emitting material such as an alumiquinoline complex, styrylamine derivative, or phthalocyanine derivative. In this case, an optically-transparent layer such as an MgAg layer may be further provided as a third layer.

When the drive system of the display formed by using the organic electroluminescent devices 11 is the active-matrix system, the cathode 15 is so formed over the substrate 12 in a blanket-film state as to be isolated from the anode 13 by the organic layer 14 and the above-described insulating film (not shown), and is used as a common electrode for the respective pixels.

It should be obvious that the structure of the cathode 15 is not limited to the above-described multilayer structure but the cathode 15 may employ the optimum film combination and multilayer structure depending on the configuration of the device to be fabricated. For example, the structure of the cathode 15 in the embodiment is a multilayer structure in which the functions of the respective layers in the electrode are separated, i.e., an inorganic layer (first layer 15a) for promoting electron injection into the organic layer 14 and an inorganic layer (second layer 15b) serving as the electrode are provided. However, the inorganic layer for promoting electron injection into the organic layer 14 may function also as the inorganic layer serving as the electrode. That is, these layers may be formed as a single-layer structure. Furthermore, it is also possible for the cathode 15 to have a multilayer structure obtained by forming a transparent electrode such as an ITO electrode on this single-layer structure.

In general, the current to be applied to the organic electroluminescent device 11 having the above-described configuration is direct current. However, pulse current or alternating current may be used. There is no particular limitation on the current value and voltage value as long as element breakdown will not occur. However, in terms of the power consumption and lifetime of the organic electroluminescent device, it is desirable that the element emits light efficiently with as low electric energy as possible.

When the organic electroluminescent device 11 has a cavity structure, the cathode 15 is formed by using a semi-transmissive/semi-reflective material. Furthermore, emitted light resulting from multiple-resonance between the light reflection plane of the anode 13 and that of the cathode 15 is extracted from the cathode side. In this case, the optical distance between the light reflection plane of the anode 13 and that of the cathode 15 is defined by the wavelength of the light that is desired to be extracted. The thicknesses of the respective layers are so designed as to achieve this optical distance. In the case of such a top-emission organic electroluminescent device, actively employing this cavity structure allows improvement in the efficiency of light extraction to the external and control of the light emission spectrum.

Moreover, it is preferable for the organic electroluminescent device 11 having such a configuration to be used in such a manner as to be covered by a protective layer (passivation layer) in order to prevent the deterioration of organic materials due to water, oxygen, and so on in the atmosphere, although the protective layer is not shown in the drawing. As the protective film, any of the following films is used: a silicon nitride (typically Si₃N₄) film, silicon oxide (typically SiO₂) film, silicon oxynitride (SiNₓO_{y} (x>y)) film, silicon nitroxide (SiOₓN_{y} (x>y)) film, thin film composed mainly of carbon such as diamond like carbon (DLC), and carbon nanotube (CN) film. It is preferable that any of these films be formed based on a single-layer or multilayer structure. Of these films, a protective film composed of a nitride is preferably used because it is dense and therefore offers an extremely-high blocking effect against water, oxygen, and any other contamination that will adversely affect the organic electroluminescent device 11.

In the embodiment, the organic electroluminescent device is a top-emission element. However, the organic electroluminescent device according to the embodiment is not limited to a top-emission element but the embodiment can be widely applied to configurations in which an organic layer including at least a light-emitting layer is provided between an anode and a cathode. Therefore, the embodiment can be applied also to a configuration obtained by sequentially stacking a cathode, an organic layer, and an anode in that order from the substrate side, and a bottom-emission (so-called transmissive) organic electroluminescent device in which the electrode disposed on the substrate side (lower electrode as the cathode or anode) is formed by using a transparent material and the electrode disposed on the opposite side to the substrate (upper electrode as the cathode or anode) is formed by using a reflective material to thereby allow light extraction only from the lower electrode side.

Moreover, the organic electroluminescent device according to the embodiment may be any element as long as it is formed by interposing an organic layer between a pair of electrodes (anode and cathode). Therefore, the organic electroluminescent device is not limited to an element formed only of a pair of electrodes and an organic layer, and the embodiment will not exclude that other constituents (e.g., inorganic compound layers and inorganic components) are also included in the element without losing an advantageous effect by the embodiment.

It is proved that the current efficiency of the organic electroluminescent device 11 having the above-described configuration is higher than that of an element including no light-enhancing layer 14d, as described in detail later in the explanation of working examples of the present invention.

Moreover, although the light-enhancing layer 14d including a blue or green light-emitting material is stacked on the red light-emitting layer 14c, color mixture due to light emission from the light-enhancing layer 14d in response to electric field application does not occur, and thus red light emission can be achieved. The reason for this feature will be as follows. Specifically, although holes that have passed through the red light-emitting layer 14c and electrons injected via the electron transport layer 14e are recombined with each other in the light-enhancing layer 14d, energy discharged due to the recombination will function to excite electrons in the host material of the adjacent red light-emitting layer 14c, and therefore will contribute to the light emission of the red light-emitting layer 14c. The occurrence of such a phenomenon can be assumed on the ground of a phenomenon that the red light-emitting layer hardly emits light when the light-enhancing layer 14d is composed only of a host material as shown later in a comparative example against a working example of the present invention.

Because of the above-described features, the organic electroluminescent device 11 having the above-described configuration is allowed to enhance the light emission efficiency of red light while keeping the color purity thereof.

Furthermore, this great improvement in the light emission efficiency allows achievement of enhancement in the luminance lifetime of the organic electroluminescent device 11 and reduction in the power consumption thereof.

### <<Schematic Configuration of Display>>

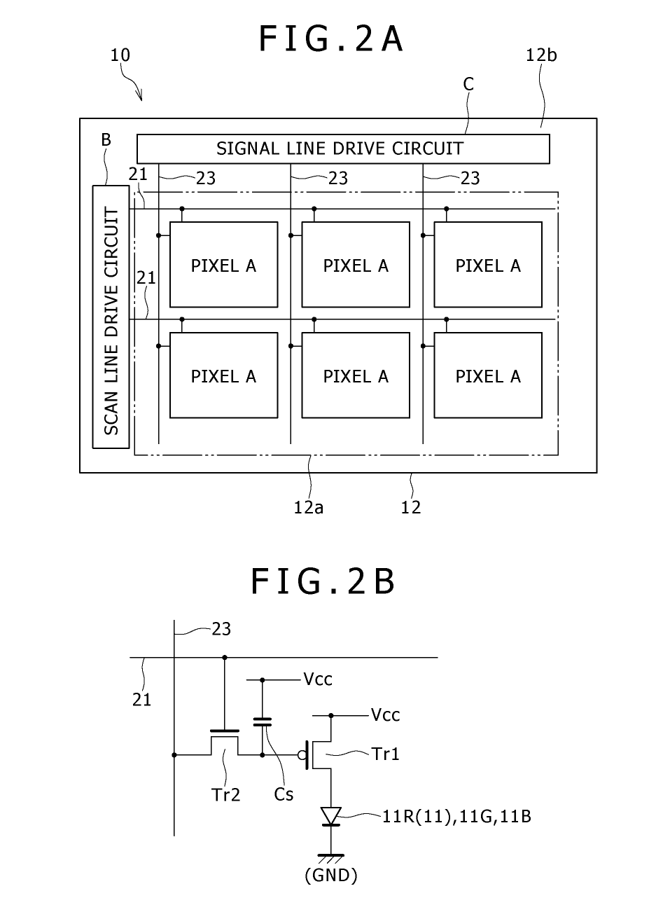

FIGS. 2A and 2B are diagrams showing one example of a display 10 according to the embodiment. FIG. 2A is a schematic configuration diagram of the display 10, and FIG. 2B is a diagram showing the configuration of a pixel circuit. The following description will deal with the active-matrix display 10 in which the organic electroluminescent devices 11 are employed as light-emitting elements.

As shown in FIG. 2A, a display area 12a and a peripheral area 12b are defined on the substrate 12 of this display 10. In the display area 12a, plural scan lines 21 and plural signal lines 23 are provided along the horizontal direction and the vertical direction, respectively. The display area 12a is formed as a pixel array part in which one pixel A is provided at each of the intersections between the scan lines 21 and the signal lines 23. In each pixel A, one of the organic electroluminescent devices 11R (11), 11G, and 11B is provided. Provided in the peripheral area 12b are a scan line drive circuit B for scan-driving the scan lines 21 and a signal line drive circuit C for supplying video signals (i.e., input signals) dependent upon luminance information to the signal lines 23.

As shown in FIG. 2B, the pixel circuit provided in each pixel A includes e.g. one of the organic electroluminescent devices 11R (11), 11G, and 11B, a drive transistor Tr1, a write transistor (sampling transistor) Tr2, and a holding capacitor Cs. Due to driving by the scan line drive circuit B, a video signal written from the signal line 23 via the write transistor Tr2 is held in the holding capacitor Cs, and the current dependent upon the amount of the held signal is supplied to the organic electroluminescent device 11R (11), 11G, or 11B, so that the organic electroluminescent device 11R (11), 11G, or 11B emits light with the luminance dependent upon the current value.

This pixel circuit configuration is merely one example, and the pixel circuit may further include an additional capacitive element and plural transistors according to need. Furthermore, a requisite drive circuit is added to the peripheral area 2b according to the change of the pixel circuit.

### <<Sectional Configuration of Display-1>>

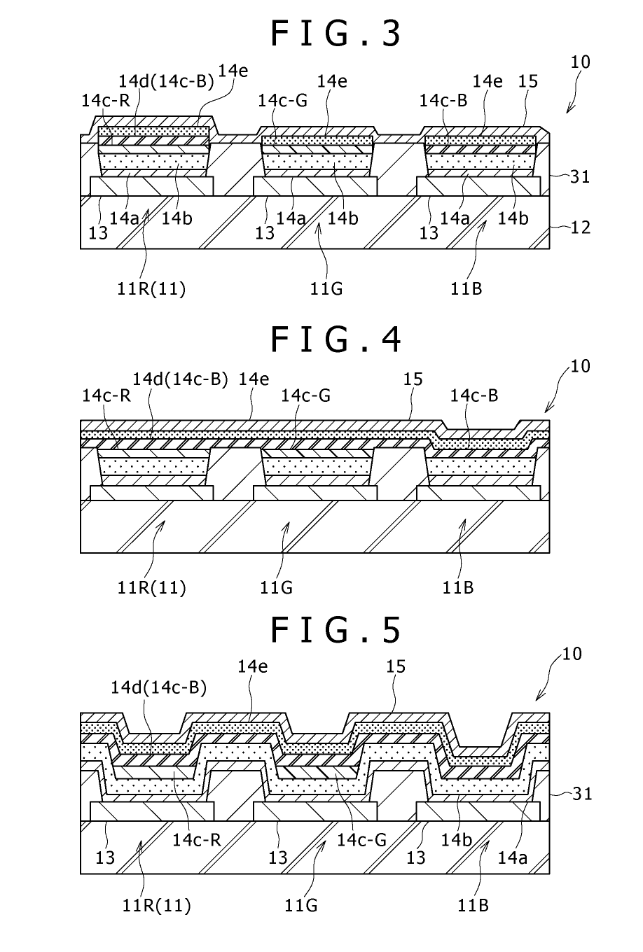

FIG. 3 shows a first example of the sectional configuration of major part in the display area of the display 10.

Although not shown in the drawing, in the display area on the substrate 12 in which the organic electroluminescent devices 11R (11), 11G, and 11B are provided, the drive transistors, the write transistors, the scan lines, and the signal lines are so provided that the above-described pixel circuits are formed (see FIG. 2), and an insulating film is provided to cover these components.

Over the substrate 12 covered by the insulating film, the organic electroluminescent devices 11R (11), 11G, and 11B are arranged. Each of the organic electroluminescent devices 11R (11), 11G, and 11B is formed as a top-emission element from which light is extracted from the opposite side to the substrate 12.

The anodes 13 of the respective organic electroluminescent devices 11R (11), 11G, and 11B are pattern-formed on an element-by-element basis. Each of the anodes 13 is connected to the drive transistor in the pixel circuit via a connection hole formed in the insulating film covering the surface of the substrate 12.

The peripheral part of each anode 13 is covered by an insulating film 31, and the center part of the anode 13 is exposed through an aperture provided in the insulating film 31. Furthermore, the organic layers 14 are pattern-formed to cover the exposed parts of the anodes 13, and the cathode 15 is provided as a common layer covering the respective organic layers 14.

Of these organic electroluminescent devices 11R (11), 11G, and 11B, particularly the red light-emitting element 11R is formed as the organic electroluminescent device (11) according to the embodiment described with FIG. 1. On the other hand, the green light-emitting element 11G and the blue light-emitting element 11B may have a general element configuration.

Specifically, in the red light-emitting element 11R (11), the organic layer 14 provided on the anode 13 is formed by sequentially stacking the hole injection layer 14a, the hole transport layer 14b, the red light-emitting layer 14c-R (14c), the light-enhancing layer 14d, and the electron transport layer 14e in that order from the anode side. The red light-emitting layer 14c-R (14c) includes a naphthacene derivative as its host material. The light-enhancing layer 14d is obtained by doping a host material with a light-emitting guest material that generates short-wavelength light such as green or blue light. In the present first example, the light-enhancing layer 14d is doped with a blue light-emitting guest material.

On the other hand, the organic layers in the green light-emitting element 11G and the blue light-emitting element 11B are formed by sequentially stacking the hole injection layer 14a, the hole transport layer 14b, the light-emitting layers 14c-G and 14c-B of the respective colors, and the electron transport layer 14e in that order from the anode side.

Because the light-enhancing layer 14d in the red light-emitting element 11R (11) is doped with a blue light-emitting guest material, the light-enhancing layer 14d may be formed based on the same configuration (material) as that of the blue light-emitting layer 14c-B in the blue light-emitting element 11B. Furthermore, the respective layers other than the light-emitting layers 14c-R, 14c-G, and 14c-B and the light-enhancing layer 14d, including the anode 13 and the cathode 15, may be formed of the same material in the respective organic electroluminescent devices 11R, 11G, and 11B, and are formed by using any of the materials described with FIG. 1.

The plural organic electroluminescent devices 11R (11), 11G, and 11B provided in the above-described manner are covered by a protective film. This protective film is so provided as to cover the whole of the display area in which the organic electroluminescent devices 11R, 11G, and 11B are provided.

The respective layers from the anode 13 to the cathode 15 in the red light-emitting element 11R (11), the green light-emitting element 11G, and the blue light-emitting element 11B can be formed by a dry process such as vacuum evaporation, ion beam method (IB method), molecular beam epitaxy (MBE), sputtering, or organic vapor phase deposition (OVPD).

When any of the layers is an organic layer, besides these methods, any of the following wet processes can also be used: laser transfer, coating methods such as spin-coating, dipping, doctor-blading, discharge-coating, and spray-coating, ink-jet method, and printing methods such as offset printing, relief printing, intaglio printing, screen printing, and micro-gravure coating. Furthermore, a dry process and a wet process may be combined depending on the properties of the respective organic layers and members.

The organic layer 14 that is pattern-formed for each of the organic electroluminescent devices 11R (11), 11G, and 11B as described above is formed by e.g. evaporation or transfer with use of a mask.

In the thus formed display 10 of the first example, the organic electroluminescent device (11) with the configuration according to the embodiment described with FIG. 1 is employed as the red light-emitting element 11R. As described above, this red light-emitting element 11R (11) is allowed to have high light emission efficiency while keeping the red light emission color. Thus, by combining the green light-emitting element 11G and the blue light-emitting element 11B with the red light-emitting element 11R (11), full-color displaying with high color reproducibility can be carried out.

Furthermore, the use of the organic electroluminescent device (11) having high light emission efficiency offers advantages that the luminance lifetime of the display 10 can be improved and the power consumption thereof can be reduced. Therefore, the display 10 can be favorably used as a flat panel display such as a wall-hung television and planar light emitter, and the organic electroluminescent device (11) can be applied to light sources of copy machines, printers, and so on, light sources of liquid crystal displays, gauges, and so on, display boards, sign lamps, etc.

### <<Sectional Configuration of Display-2>>

FIG. 4 shows a second example of the sectional configuration of major part in the display area of the display 10.

The display 10 of the second example shown in FIG. 4 is different from the first example shown in FIG. 3, in that the layers above the light-emitting layers 14c-R and 14c-G are continuously formed as common layers in the respective organic electroluminescent devices 11R (11), 11G, and 11B. The configuration of the second example except for this feature may be the same as that of the first example. In the second example, the blue light-emitting layer 14c-B, the electron transport layer 14e, and the cathode 15 are provided as common layers covering plural pixels.

The blue light-emitting layer 14c-B as a common layer is provided as the light-enhancing layer 14d in the red light-emitting element 11R (11). On the other hand, blue light generated by the blue light-emitting layer 14c-B provided in the green light-emitting element 11G is absorbed in the green light-emitting layer 14c-G and contributes to green light emission. In this display 10, the color purity of emitted light to be extracted is enhanced if the organic layer is formed to have a cavity structure for extracting emitted light of the corresponding color in each of the organic electroluminescent devices 11R (11), 11G, and 11B.

The thus formed display 10 of the second example can achieve the same advantages as those of the first example. In particular, each of the upper layers from the blue light-emitting layer 14c-B (light-enhancing layer 14d) can be collectively deposited for the display area by using an area mask with a large-size aperture. This can simplify the manufacturing step for the display 10.

### <<Sectional Configuration of Display-3>>

FIG. 5 shows a third example of the sectional configuration of major part in the display area of the display 10.

In the display 10 of the third example shown in FIG. 5, the layers other than the anodes 13 and the light-emitting layers 14c-R and 14c-G are formed as common layers in the respective organic electroluminescent devices 11R (11), 11G, and 11B. The configuration of the third example except for this feature may be the same as that of the first example. Specifically, in addition to the blue light-emitting layer 14c-B (light-enhancing layer 14d), the electron transport layer 14e, and the cathode 15, which are used as common layers in the second example, the hole injection layer 14a and the hole transport layer 14b below the light-emitting layers are also used as common layers.

The thus formed display 10 of the third example can also achieve the same advantages as those of the second example, and can be formed by a further simplified manufacturing step compared with the second example.

### <<Sectional Configuration of Display-4>>

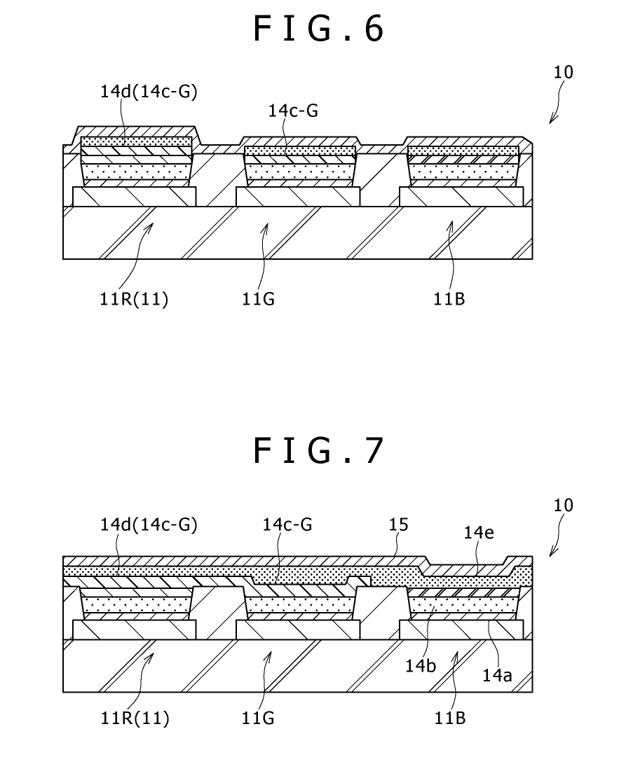

FIG. 6 shows a fourth example of the sectional configuration of major part in the display area of the display 10.

The display 10 of the fourth example shown in FIG. 6 is different from the first example shown in FIG. 3, in that the light-enhancing layer 14d in the red light-emitting element 11R (11) is doped with a green light-emitting guest material. The configuration of the fourth example except for this feature is the same as that of the first example.

In this case, the light-enhancing layer 14d in the red light-emitting element 11R (11) may have the same configuration as that of the green light-emitting layer 14c-G in the green light-emitting element 11G. The features except for this light-enhancing layer 14d may be the same as those of the first example.

The thus formed display 10 of the fourth example can also achieve the same advantages as those of the first example.

### <<Sectional Configuration of Display-5>>

FIG. 7 shows a fifth example of the sectional configuration of major part in the display area of the display 10.

The display 10 of the fifth example shown in FIG. 7 is different from the fourth example shown in FIG. 6, in that the light-enhancing layer 14d (14c-G) and the light-emitting layer 14c-G are formed as a common layer to the organic electroluminescent devices 11R (11) and 11G and the electron transport layer 14e is formed as a common layer to all the pixels. The configuration of the fifth example except for this feature may be the same as that of the fourth example.

The thus formed display 10 of the fifth example can also achieve the same advantages as those of the first example. Moreover, the manufacturing step for the display 10 can be simplified because the light-enhancing layer 14d (14c-G) and the light-emitting layer 14c-G can be formed as a common layer in the organic electroluminescent devices 11R (11) and 11G and the electron transport layer 14e can be deposited simultaneously for all the pixels.

### <<Sectional Configuration of Display-6>>

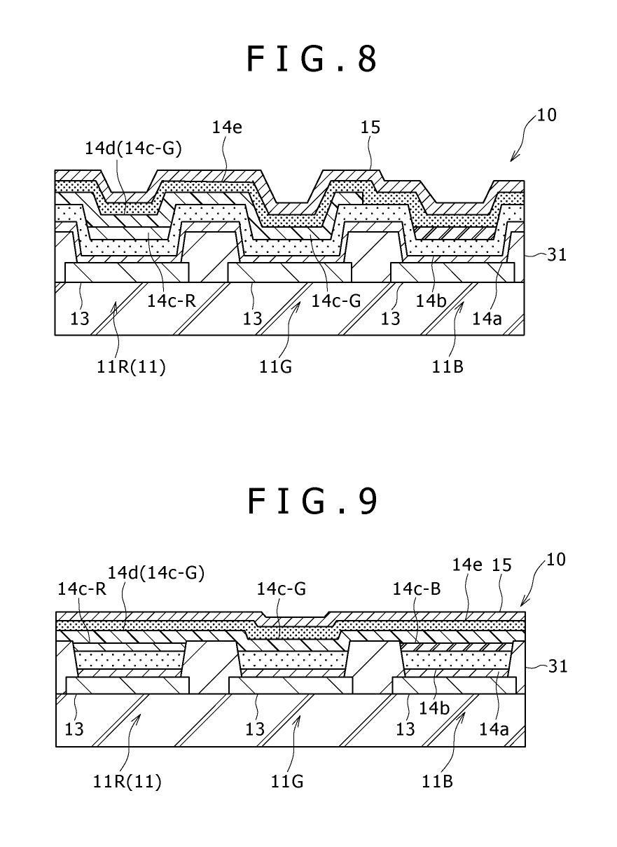

FIG. 8 shows a sixth example of the sectional configuration of major part in the display area of the display 10.

In the display 10 of the sixth example shown in FIG. 8, the layers other than the anodes 13 and the light-emitting layers 14c-R, 14c-G, and 14c-B are formed as common layers in the respective organic electroluminescent devices 11R (11), 11G, and 11B. The configuration of the sixth example except for this feature may be the same as that of the fifth example shown in FIG. 7. Specifically, as the difference from the fifth example in FIG. 7, the hole injection layer 14a and the hole transport layer 14b below the light-emitting layers are also used as common layers.

The thus formed display 10 of the sixth example can also achieve the same advantages as those of the fifth example, and can be formed by a further simplified manufacturing step compared with the fifth example.

### <<Sectional Configuration of Display-7>>

FIG. 9 shows a seventh example of the sectional configuration of major part in the display area of the display 10.

As shown in this drawing, the layers above the light-emitting layers 14c-R and 14c-B may be formed as common layers in the respective organic electroluminescent devices 11R, 11G, and 11B. In this case, the green light-emitting layer 14c-G serving also as the light-enhancing layer 14d, the electron transport layer 14e, and the cathode 15 are each formed as a common layer to the entire display area, whereas the other layers are each used as a patterned layer.

The green light-emitting layer 14c-G common to all the pixels is provided as the light-enhancing layer 14d in the red light-emitting element 11R (11). This green light-emitting layer 14c-G is provided also in the blue light-emitting element 11B. Even with such a configuration, however, it is sufficiently possible to obtain blue light emission with favorable chromaticity if the film thickness of the blue light-emitting layer 14c-B is sufficiently large or if the luminescent center of the blue light emission is localized at the interface with the hole transport layer 14b. Moreover, the display 10 may be so configured that only blue light is extracted from the blue light-emitting element 11B by forming organic layers each having a cavity structure for extracting emitted light of a corresponding one of the colors in the respective organic electroluminescent devices 11R (11), 11G, and 11B.

In manufacturing of the display 10 having such a configuration, each of the upper layers from the green light-emitting layer 14c-G (light-enhancing layer 14d) can be collectively deposited for the display area by using an area mask with a large-size aperture. Thus, the manufacturing step for the display 10 can be simplified.

Also in the seventh example, it is also possible that the hole injection layer 14a and the hole transport layer 14b below the light-emitting layers are each used as a common layer for the entire display area. This can further simplify the manufacturing step for the display 10.

In the above-described first to seventh examples, the embodiment is applied to an active-matrix display. However, the display according to the embodiment can be applied also to a passive-matrix display and can achieve the same advantages.

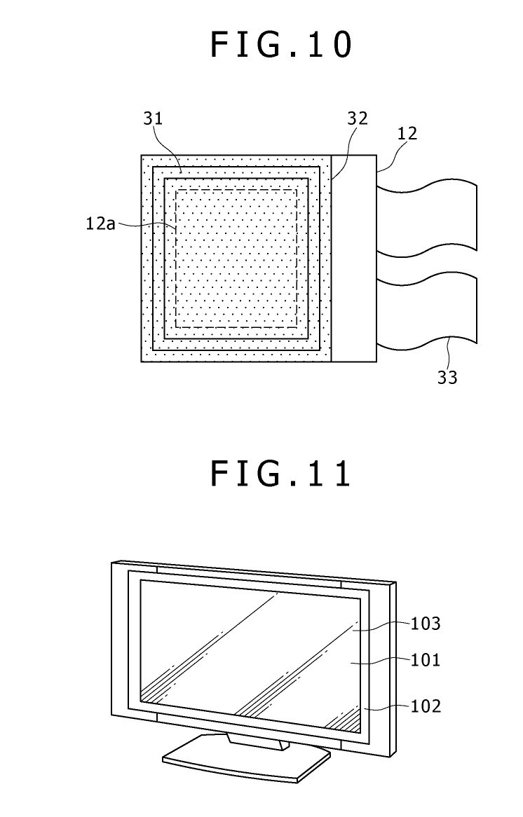

The above-described display according to the embodiment encompasses also a module-shape display having a sealed structure like that shown in FIG. 10. For example, the display module shown in FIG. 10 is formed by providing a sealing part 31 surrounding the display area 12a as a pixel array part and bonding the display to a counter member (sealing substrate 32) such as a transparent glass substrate by use of the sealing part 31 as an adhesive. This transparent sealing substrate 32 may be provided with a color filer, protective film, light-shielding film, and so on. The substrate 12 as the display module on which the display area 12a is formed may be provided with a flexible printed board 33 for external input/output of signals and so on to/from the display area 12a (pixel array part).

### APPLICATION EXAMPLES

The above-described display according to the embodiment can be applied to various kinds of electronic apparatus shown in FIGS. 11 to 15. Specifically, the display can be used as a display in electronic apparatus in any field that displays a video signal input thereto or produced therein as an image and video, such as a digital camera, notebook personal computer, portable terminal apparatus such as a cellular phone, and video camera. Examples of electronic apparatus to which the embodiment is applied will be described below.

FIG. 11 is a perspective view showing a television to which the embodiment is applied. This television includes a video display screen 101 formed of a front panel 102, a filter glass 103, and so on, and is fabricated by using the display according to the embodiment as the video display screen 101.

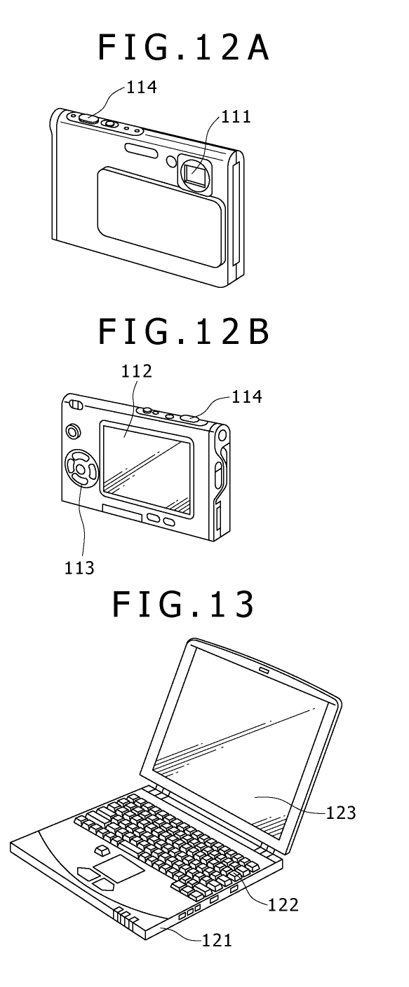

FIG. 12 is a diagram showing a digital camera to which the embodiment is applied: 12A is a front-side perspective view and 12B is a rear-side perspective view. This digital camera includes a light emitter 111 for flash, a display part 112, a menu switch 113, a shutter button 114, and so on, and is fabricated by using the display according to the embodiment as the display part 112.

FIG. 13 is a perspective view showing a notebook personal computer to which the embodiment is applied. This notebook personal computer includes in a main body 121 thereof a keyboard 122 operated in inputting of characters and so on, a display part 123 for displaying images, and so on. The notebook personal computer is fabricated by using the display according to the embodiment as the display part 123.

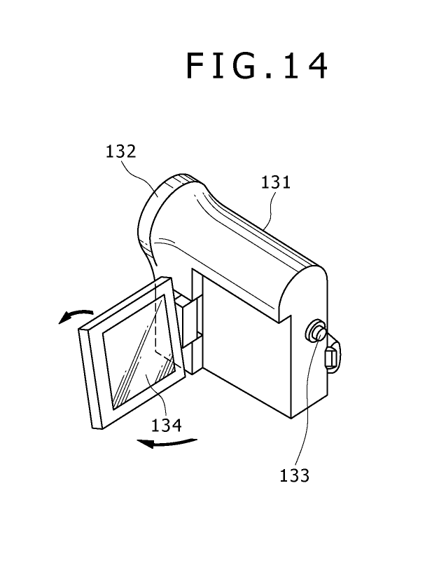

FIG. 14 is a perspective view showing a video camera to which the embodiment is applied. This video camera includes a main body 131, a lens 132 that is disposed on the front side of the camera and used to capture a subject image, a start/stop switch 133 regarding imaging, a display part 134, and so on. The video camera is fabricated by using the display according to the embodiment as the display part 134.

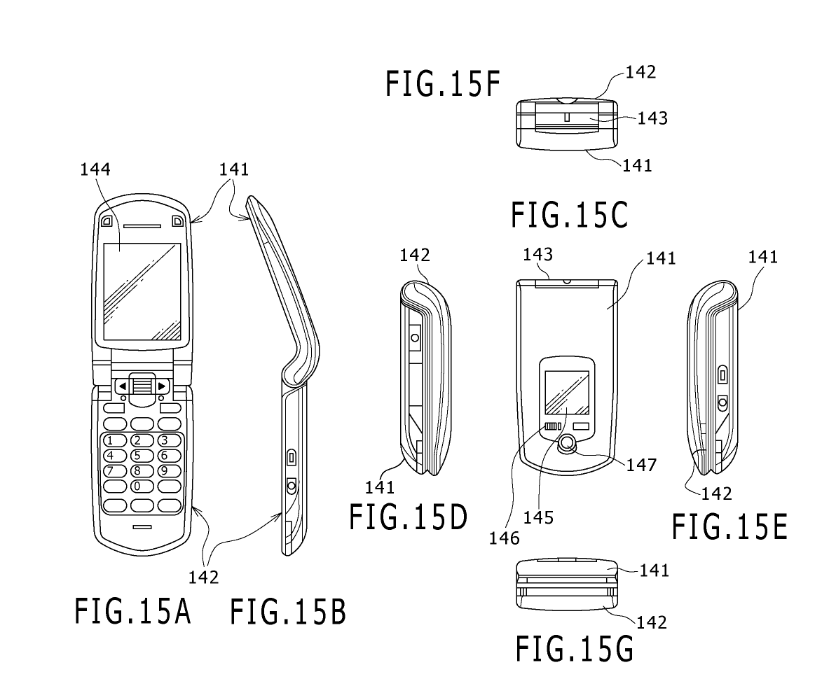

FIG. 15 is a diagram showing a cellular phone as portable terminal apparatus to which the embodiment is applied: 15A and 15B are a front view and side view, respectively, of the opened state, and 15C, 15D, 15E, 15F and 15G are a front view, left-side view, right-side view, top view, and bottom view, respectively, of the closed state. This cellular phone includes an upper casing 141, a lower casing 142, a connection (hinge) 143, a display 144, a sub-display 145, a picture light 146, a camera 147, and so on. The cellular phone is fabricated by using the display according to the embodiment as the display 144 and the sub-display 145.

The above-described applications are merely one example.

### WORKING EXAMPLES

Manufacturing procedures for organic electroluminescent devices of specific working examples of the present invention and comparative examples will be described below with reference to FIG. 1, and subsequently results of evaluation on these elements will be described.

### Working Examples 1 to 4

Initially, on the substrate 12 formed of a glass plate with a size of 30 mm×30 mm, a cell for a top-emission organic electroluminescent device was fabricated as the anode 13. The cell was formed by stacking an ITO transparent electrode with a thickness of 12.5 nm on an Ag alloy layer (reflective layer) with a thickness of 190 nm.

Subsequently, as the hole injection layer 14a in the organic layer 14, a film composed of m-MTDATA represented by Structural formula (101) was formed to a thickness of 12 nm by vacuum evaporation (at an evaporation rate of 0.2 to 0.4 nm/sec). Note that the m-MTDATA refers to 4,4′,4″-tris(phenyl-m-tolylamino)triphenylamine.

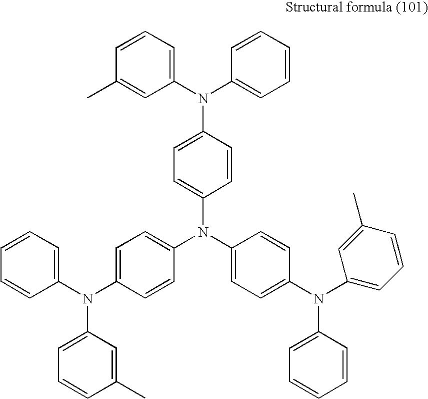

Subsequently, as the hole transport layer 14b, a film composed of α-NPD represented by Structural formula (102) was formed to a thickness of 12 nm (at an evaporation rate of 0.2 to 0.4 nm/sec). Note that the α-NPD refers to N,N′-bis(1-naphthyl)-N,N′-diphenyl[1,1′-biphenyl]-4,4′-diamine.

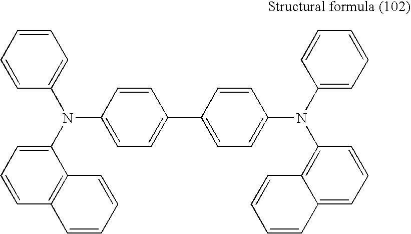

Subsequently, on the hole transport layer 14b, the light-emitting layer 14c having a thickness of 30 nm was deposited by evaporation. For the formation of the light-emitting layer 14c, rubrene was used as the host material, and the host material was doped with a dibenzo[f,f′]diindeno[1,2,3-cd:1′,2′,3′-lm]perylene derivative represented by Structural formula (103) as a red light-emitting guest material. The doping amount was 1% in the relative thickness ratio.

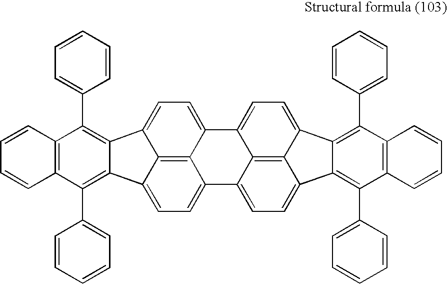

On the thus formed light-emitting layer 14c, the light-enhancing layer 14d having a thickness of 25 nm was deposited by evaporation. For the formation of the light-enhancing layer 14d, 9,10-di(2-naphthyl)anthracene (ADN) represented by Structural formula (104) was used as the host material, and the host material was doped with a styrylamine derivative represented by Structural formula (105) as a blue light-emitting guest material. The doping amount (relative thickness ratio) of the blue light-emitting guest material was set to 2%, 5%, 10%, and 15% in Working examples 1, 2, 3, and 4, respectively.

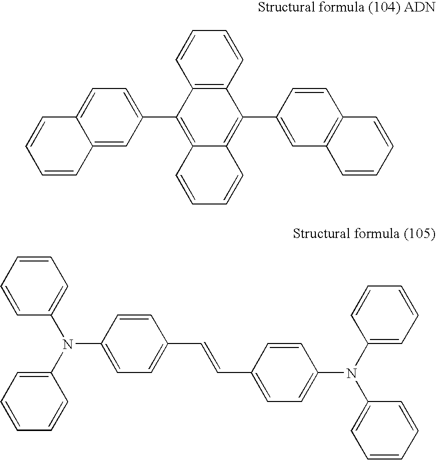

Subsequently, as the electron transport layer 14e, Alq3 (8-hydroxyquinoline aluminum) represented by Structural formula (106) was deposited to a thickness of 10 nm by evaporation.

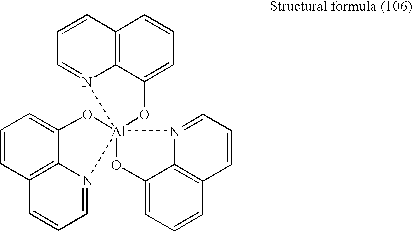

After the organic layer 14 was formed by sequentially stacking the hole injection layer 14a, the hole transport layer 14b, the light-emitting layer 14c, the light-enhancing layer 14d, and the electron transport layer 14e as described above, a film composed of LiF was formed as the first layer 15a of the cathode 15 to a thickness of about 0.3 nm by vacuum evaporation (at an evaporation rate of 0.01 nm/sec). At last, an MgAg film with a thickness of 10 nm was formed as the second layer 15b of the cathode 15 on the first layer 15a by vacuum evaporation.

In the above-described manner, the organic electroluminescent devices of Working examples 1 to 4 were fabricated.

### Working Examples 5 to 9

In the formation of the light-enhancing layer 14d in the fabrication procedure for the organic electroluminescent devices of Working examples 1 to 4, materials represented by Structural formulas (107) to (111) were used as a blue light-emitting guest material in Working examples 5 to 9, respectively. The doping amounts (relative thickness ratios) of the guest material were set to the values shown in Table 1. Except for this feature, the elements were fabricated in the same manner as that for Working examples 1 to 4.

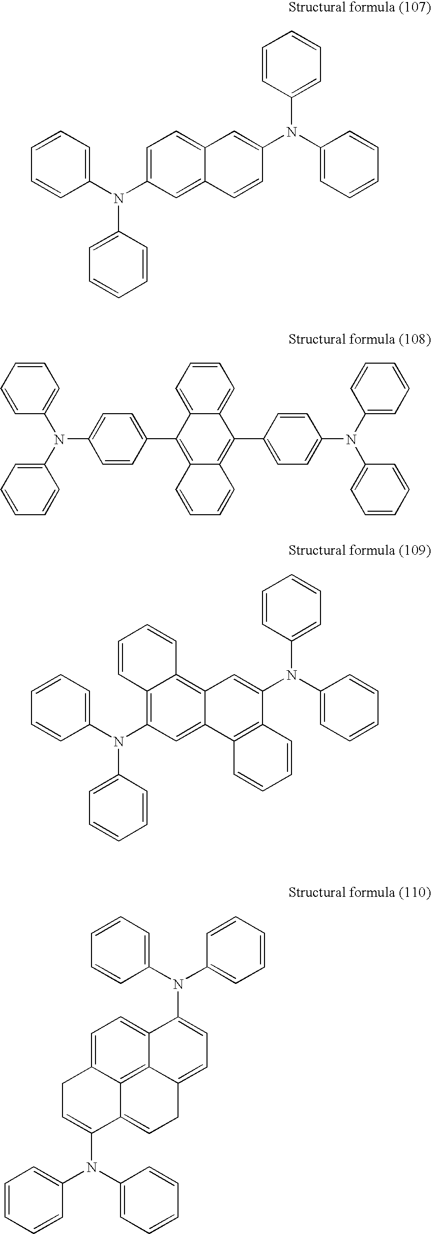

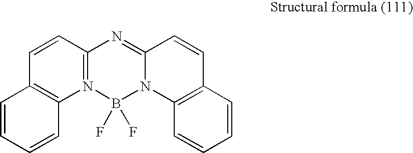

TABLE 1

| | | | Light- | | | | | |
|---|---|---|---|---|---|---|---|---|
| | Light- | | enhancing | | | | | |
| | emitting | | layer 14d | | | Drive | Current | Color |
| | layer 14c | | | | Guest | voltage | efficiency | coordinate |
| | Host | Guest | Host | Guest | ratio | [V] | [cd/A] | (x, y) |
| Working | Rubrene | Formula | ADN | Formula | 2.0% | 7.4 | 12.9 | (0.64, 0.34) |
| example 1 | | 103 | | (105) | | | | |
| Working | | | | | 5.0% | 7.4 | 13.1 | (0.64, 0.34) |
| example 2 | | | | | | | | |
| Working | | | | | 10.0% | 7.6 | 13.2 | (0.64, 0.34) |
| example 3 | | | | | | | | |
| Working | | | | | 15.0% | 7.8 | 11.5 | (0.64, 0.34) |
| example 4 | | | | | | | | |
| Working | | | | Formula | 5.0% | 7.5 | 9.5 | (0.64, 0.34) |
| example 5 | | | | (107) | | | | |
| Working | | | | Formula | 5.0% | 7.7 | 12.1 | (0.64, 0.34) |
| example 6 | | | | (108) | | | | |
| Working | | | | Formula | 7.5% | 7.2 | 12.5 | (0.64, 0.34) |
| example 7 | | | | (109) | | | | |
| Working | | | | Formula | 5.0% | 7.7 | 12.7 | (0.64, 0.34) |
| example 8 | | | | (110) | | | | |
| Working | | | | Formula | 1.0% | 7.1 | 10.5 | (0.64, 0.34) |
| example 9 | | | | (111) | | | | |
| Comparative | | | — | — | — | 7.5 | 6.5 | (0.64, 0.33) |
| example 1 | | | | | | | | |
| Comparative | | | ADN | — | — | 7.6 | 0.5 | (0.65, 0.37) |
| example 2 | | | | | | | | |

### Comparative Example 1

The formation of the light-enhancing layer 14d in the fabrication procedure for the organic electroluminescent devices of Working examples 1 to 4 was not carried out. Instead, the thickness of the electron transport layer composed of Alq3 (8-hydroxyquinoline aluminum) was increased to 45 nm. Except for this feature, the elements were fabricated in the same manner as that for Working examples 1 to 4.

### Comparative Example 2

In the formation of the light-enhancing layer 14d in the fabrication procedure for the organic electroluminescent devices of Working examples 1 to 4, the light-enhancing layer 14d was formed by using only the host material without doping the host material with a blue light-emitting guest material. Except for this feature, the elements were fabricated in the same manner as that for Working examples 1 to 4.

### <Evaluation Results>

Regarding each of the organic electroluminescent devices of Working examples 1 to 9 and Comparative examples 1 and 2, the drive voltage (V), the current efficiency (cd/A), and the color coordinate (x, y) when the element was driven with a current density of 10 mA/cm² were measured. The measurement results are shown in Table 1.

As shown in Table 1, all of the organic electroluminescent devices of Working examples 1 to 9, to which the embodiment was applied, showed high current efficiency about twice that of the organic electroluminescent devices of Comparative examples 1 and 2, to which the embodiment was not applied, when the drive voltage was substantially equivalent. This proves that energy arising from recombination in the light-enhancing layer 14d composed of the host material (ADN) and a light-emitting guest material offers an effect of light enhancement (increase in the light emission amount) in the light-emitting layer 14c.

Furthermore, from the organic electroluminescent devices of Working examples 1 to 9, in which the light-enhancing layer 14d formed by doping the host with a blue light-emitting guest was stacked on the red light-emitting layer 14c, the emission of red light of which color coordinate was (0.64, 0.34) was measured, and hence these elements involved no influence of color mixing due to blue light emission. In particular, the color coordinate of the emitted light was (0.64, 0.34) in all of the organic electroluminescent devices of Working examples 5 to 9, in which the kind of light-emitting guest material mixed in the light-enhancing layer 14d was changed from each other. This proves that the configuration of the embodiment allows extraction of red light generated by the red light-emitting layer 14c irrespective of the light-emitting guest material in the light-enhancing layer 14d.

From the above-described results, it is proved that the light emission efficiency (current efficiency) can be greatly enhanced while the color purity of red light is kept due to the configuration of the embodiment in which materials selected from publicly-known organic materials are used as the host material and the dopant material in the red light-emitting layer 14c and the light-enhancing layer 14d containing any of various blue light-emitting guest materials is provided adjacent to this light-emitting layer 14c.

Furthermore, this indicates that full-color displaying with high color reproducibility can be carried out by forming the pixels by paring this organic electroluminescent device with green and blue light-emitting elements.

### Working Examples 10 to 13

Organic electroluminescent devices were fabricated by the same procedure as that for Working examples 1 to 4, except that the light-emitting guest material used in the formation of the light-enhancing layer 14d was changed to a green light-emitting guest material. In Working examples 10 to 13, a diaminoanthracene derivative represented by Structural formula (112) was used as the green light-emitting guest material. The doping amount (relative thickness ratio) of the green light-emitting guest material was set to 2%, 5%, 10%, and 15% in Working examples 10, 11, 12, and 13, respectively.

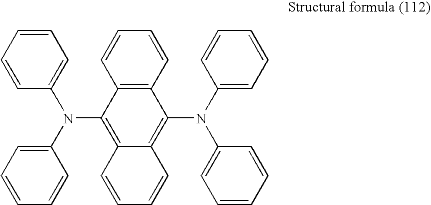

The diaminoanthracene derivative represented by Structural formula (112) was synthesized based on a description in the paper “Chemistry of Materials, Vol. 14, p. 3958-3963, 2002”.

### Working Examples 14 to 18

In the formation of the light-enhancing layer 14d in the fabrication procedure for the organic electroluminescent devices of Working examples 1 to 4, materials represented by Structural formulas (113) to (117) were used as a green light-emitting guest material in Working examples 14 to 18, respectively. The doping amount of the guest material was set to 5% in the relative thickness ratio in Working example 14, and to 1% in the relative thickness ratio in Working examples 15 to 18. Except for this feature, the elements were fabricated in the same manner as that for Working examples 1 to 4.

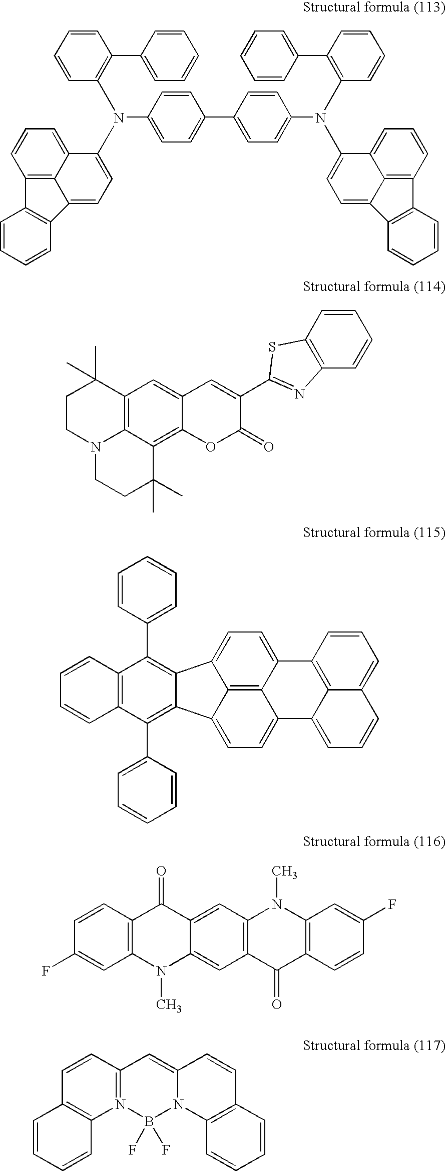

The compound of Structural formula (113) used in Working example 14 was synthesized based on a synthesis method described in Japanese Patent Laid-open No. 2006-96964.

The compound of Structural formula (114) used in Working example 15 was synthesized based on a synthesis method described in Japanese Patent Laid-open No. 2000-182772.

The compound of Structural formula (115) used in Working example 16 was synthesized based on a synthesis method described in Japanese Patent Laid-open No. 2003-347057.

The compound of Structural formula (116) used in Working example 17 was synthesized based on a synthesis method described in Japanese Patent Laid-open No. 9-176630.

The compound of Structural formula (117) used in Working example 18 was synthesized based on a synthesis method described in Japanese Patent Laid-open No. 2003-288990.

### <Evaluation Results>

Regarding each of the organic electroluminescent devices of Working examples 10 to 18, the drive voltage (V), the current efficiency (cd/A), and the color coordinate (x, y) when the element was driven with a current density of 10 mA/cm² were measured. The measurement results are shown in Table 2. The above-described results of Comparative examples 1 and 2 are also shown in Table 2.

TABLE 2

| | Light- | | Light- | | | | | |
|---|---|---|---|---|---|---|---|---|
| | emitting | | enhancing | | | | | |
| | layer | | layer 14d | | | | | |
| | 14c | | | | Guest | Drive voltage | Current efficiency | Color coordinate |
| | Host | Guest | Host | Guest | ratio | [V] | [cd/A] | (x, y) |
| Working | Rubrene | Formula | ADN | Formula | 2.0% | 7.5 | 13.1 | (0.64, 0.34) |
| example 10 | | (103) | | (112) | | | | |
| Working | | | | | 5.0% | 7.5 | 13.5 | (0.64, 0.34) |
| example 11 | | | | | | | | |
| Working | | | | | 10.0% | 7.8 | 13.9 | (0.64, 0.34) |
| example 12 | | | | | | | | |
| Working | | | | | 15.0% | 7.7 | 11.0 | (0.64, 0.34) |
| example 13 | | | | | | | | |
| Working | | | | Formula | 5.0% | 7.3 | 13.2 | (0.64, 0.34) |
| example 14 | | | | (113) | | | | |
| Working | | | | Formula | 1.0% | 7.5 | 12.5 | (0.64, 0.34) |
| example 15 | | | | (114) | | | | |
| Working | | | | Formula | 1.0% | 7.6 | 12.5 | (0.64, 0.34) |
| example 16 | | | | (115) | | | | |
| Working | | | | Formula | 1.0% | 7.5 | 11.3 | (0.64, 0.34) |
| example 17 | | | | (116) | | | | |
| Working | | | | Formula | 1.0% | 7.8 | 10.8 | (0.64, 0.34) |
| example 18 | | | | (117) | | | | |
| Comparative | | | — | — | — | 7.5 | 6.5 | (0.64, 0.33) |
| example 1 | | | | | | | | |
| Comparative | | | ADN | — | — | 7.6 | 0.5 | (0.65, 0.37) |
| example 2 | | | | | | | | |

As shown in Table 2, all of the organic electroluminescent devices of Working examples 10 to 18, to which the embodiment was applied, showed high current efficiency about twice that of the organic electroluminescent devices of Comparative examples 1 and 2, to which the embodiment was not applied, when the drive voltage was substantially equivalent. This proves that energy arising from recombination in the light-enhancing layer 14d composed of the host material (ADN) and a light-emitting guest material offers an effect of light enhancement (increase in the light emission amount) in the light-emitting layer 14c.

Furthermore, from the organic electroluminescent devices of Working examples 10 to 18, in which the light-enhancing layer 14d formed by doping the host with a green light-emitting guest was stacked on the red light-emitting layer 14c, the emission of red light of which color coordinate was (0.64, 0.34) was measured, and hence these elements involved no influence of color mixing due to green light emission. In particular, the color coordinate of the emitted light was (0.64, 0.34) in all of the organic electroluminescent devices of Working examples 14 to 18, in which the kind of light-emitting guest material mixed in the light-enhancing layer 14d was changed from each other. This proves that the configuration of the embodiment allows extraction of red light generated by the red light-emitting layer 14c irrespective of the light-emitting guest material in the light-enhancing layer 14d.

From the above-described results, it is proved that the light emission efficiency (current efficiency) can be greatly enhanced while the color purity of red light is kept due to the configuration of the embodiment in which materials selected from publicly-known organic materials are used as the host material and the dopant material in the red light-emitting layer 14c and the light-enhancing layer 14d containing any of various green light-emitting guest materials is provided adjacent to this light-emitting layer 14c.

Furthermore, this indicates that full-color displaying with high color reproducibility can be carried out by forming the pixels by paring this organic electroluminescent device with green and blue light-emitting elements.

### Working Example 19

A display employing the same organic electroluminescent device as that of Working example 1 was fabricated in the following manner (see FIG. 5).

Initially, the anodes 13 were pattern-formed on the display area of the substrate 12, and the insulating film 31 having apertures that expose the center parts of the respective anodes 13 was formed. Subsequently, with use of a mask having a large-size aperture corresponding to the entire display area, the hole injection layer 14a and the hole transport layer 14b were formed by the same procedure as that of Working example 1.

Subsequently, with use of a stripe mask having apertures corresponding to the formation areas for red light-emitting elements (red areas), the light-emitting layer 14c (14c-R) was deposited only in the red areas in the same manner as that of Working example 1. Furthermore, with use of a stripe mask having apertures corresponding to the formation areas for green light-emitting elements (green areas), the light-emitting layer 14c-G for the green areas was deposited.

Thereafter, by using the mask having the large-size aperture corresponding to the entire display area again, the blue light-emitting layer 14c-B serving also as the light-enhancing layer 14d, the electron transport layer 14e, and the cathode 15 were deposited in that order in the same manner as that of Working example 1.

Through the above-described steps, a display was obtained in which the organic electroluminescent devices of Working example 1, to which the embodiment was applied, were formed as red light-emitting elements in the red areas, and green and blue light-emitting elements were formed in the green and blue areas, respectively.

### Working Example 20

A display employing the same organic electroluminescent device as that of Working example 10 was fabricated in the following manner (see FIG. 8).

Initially, the anodes 13 were pattern-formed on the display area of the substrate 12, and the insulating film 31 having apertures that expose the center parts of the respective anodes 13 was formed. Subsequently, with use of a mask having a large-size aperture corresponding to the entire display area, the hole injection layer 14a and the hole transport layer 14b were formed by the same procedure as that of Working example 1.

Subsequently, with use of a stripe mask having apertures corresponding to the formation areas for red light-emitting elements (red areas), the light-emitting layer 14c (14c-R) was deposited only in the red areas in the same manner as that of Working example 1. Furthermore, with use of a stripe mask having apertures corresponding to the formation areas for blue light-emitting elements (blue areas), the light-emitting layer 14c-B for the blue areas was deposited.

After the deposition of the red light-emitting layer 14c (14c-R), by using a stripe mask having middle-size apertures corresponding to the red areas and the green areas, the green light-emitting layer 14c-G serving also as the light-enhancing layer 14d was deposited in the same manner as that of Working example 10.

Subsequently, with use of the mask having the large-size aperture corresponding to the entire display area, the electron transport layer 14e was deposited and the cathode 15 having a two-layer structure was formed in the same manner as that of Working example 1.

Through the above-described steps, a display was obtained in which the organic electroluminescent devices of Working example 10, to which the embodiment was applied, were formed as red light-emitting elements in the red areas, and green and blue light-emitting elements were formed in the green and blue areas, respectively.

### Working Example 21

A display employing the same organic electroluminescent device as that of Working example 10 was fabricated in the following manner. The display has a configuration obtained by changing layers below the light-emitting layers in the configuration of FIG. 9 to common layers.

Initially, the anodes 13 were pattern-formed on the display area of the substrate 12, and the insulating film 31 having apertures that expose the center parts of the respective anodes 13 was formed. Subsequently, with use of a mask having a large-size aperture corresponding to the entire display area, the hole injection layer 14a and the hole transport layer 14b were formed by the same procedure as that of Working example 1.

Subsequently, with use of a stripe mask having apertures corresponding to the formation areas for red light-emitting elements (red areas), the light-emitting layer 14c (14c-R) was deposited only in the red areas in the same manner as that of Working example 1. Furthermore, with use of a stripe mask having apertures corresponding to the formation areas for blue light-emitting elements (blue areas), the light-emitting layer 14c-B for the blue areas was deposited.

Thereafter, by using the mask having the large-size aperture corresponding to the entire display area on the substrate, the green light-emitting layer 14c-G serving also as the light-enhancing layer 14d was deposited in the same manner as that of Working example 10, and then the electron transport layer 14e and the cathode 15 were deposited.

Through the above-described steps, a display was obtained in which the organic electroluminescent devices of Working example 10, to which the embodiment was applied, were formed as red light-emitting elements in the red areas, and green and blue light-emitting elements were formed in the green and blue areas, respectively.

It should be understood by those skilled in the art that various modifications, combinations, sub-combinations and alterations may occur depending on design requirements and other factor in so far as they are within the scope of the appended claims or the equivalents thereof.

What is claimed is:

1. An organic electroluminescent device for emitting red light, comprising
an organic layer including a light-emitting layer provided between an anode and a cathode, the light-emitting layer containing a red light-emitting guest material and a host material that is composed of a polycyclic aromatic hydrocarbon compound having a skeleton with four- to seven-membered rings, wherein
a light-enhancing layer that contains a light-emitting guest material for generating light having a wavelength shorter than a wavelength of light emitted by the light-emitting layer is provided adjacent to the light-emitting layer.

2. The organic electroluminescent device according to claim 1, wherein
a compound represented as General formula (1) is used as the red light-emitting guest material, 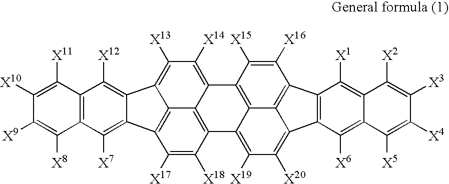
where X¹ to X²⁰ each independently denote hydrogen, a halogen, a hydroxyl group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

3. The organic electroluminescent device according to claim 1, wherein
the skeleton of the polycyclic aromatic hydrocarbon compound of the host material is selected from pyrene, benzopyrene, chrysene, naphthacene, benzonaphthacene, dibenzonaphthacene, perylene, and coronene.

4. The organic electroluminescent device according to claim 1, wherein
a compound represented as General formula (2) is used as the host material of the light-emitting layer, 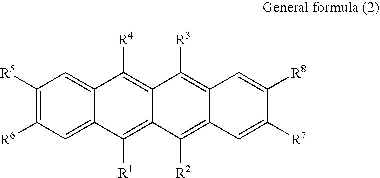
where R1 to R8 each independently denote hydrogen, a halogen, a hydroxyl group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

5. The organic electroluminescent device according to claim 1, wherein
the light-enhancing layer is provided between the light-emitting layer and the cathode.

6. The organic electroluminescent device according to claim 1, wherein
red light generated by the light-emitting layer is extracted through one of the anode and the cathode after being multiply-resonated between any layers existing between the anode and the cathode.

7. A display obtained by forming over a substrate a plurality of organic electroluminescent devices for emitting red light, each of the organic electroluminescent devices comprising
an organic layer including a light-emitting layer provided between an anode and a cathode, the light-emitting layer containing a red light-emitting guest material and a host material that is composed of a polycyclic aromatic hydrocarbon compound having a skeleton with four- to seven-membered rings, wherein
a light-enhancing layer that contains a light-emitting guest material for generating light having a wavelength shorter than a wavelength of light emitted by the light-emitting layer is provided adjacent to the light-emitting layer.

8. The display according to claim 7, wherein
the organic electroluminescent devices are provided as red light-emitting elements in a part of a plurality of pixels.

9. The display according to claim 8, wherein
the light-enhancing layer in the organic electroluminescent device provided as the red light-emitting element covers a plurality of pixels so as to function as a common light-emitting layer.

10. The display according to claim 8, wherein
organic electroluminescent devices for blue light emission and organic electroluminescent devices for green light emission are provided over the substrate together with the red light-emitting elements.
